(19) United States
(12) Patent Application Publication
(10) Pub. No.: US 2025/0086349 A1
(43) Pub. Date: Mar. 13, 2025

(54) SERVER FOR DIAGNOSING BATTERY ABNORMALITY, METHOD OF CONSTRUCTING DIAGNOSTIC MODEL THEREFOR, AND METHOD OF DIAGNOSING ABNORMAL STATE OF BATTERY USING SAME

(71) Applicants: HYUNDAI MOTOR COMPANY, Seoul (KR); Kia Corporation, Seoul (KR)

(72) Inventor: Yoon Sung CHOI, Hwaseong-si (KR)

(21) Appl. No.: 18/612,822

(22) Filed: Mar. 21, 2024

(30) Foreign Application Priority Data
Sep. 8, 2023 (KR) 10-2023-0119785

(51) Int. Cl. G06F 30/20

(52) U.S. Cl. CPC G06F 30/20

(57) ABSTRACT

Disclosed is a server for diagnosing a battery abnormality. The server includes a memory that stores a diagnostic model for determining an abnormal state of a target battery, and a processor that is connected to the memory, wherein the processor classifies learning battery information in a form of time series data provided from each of a plurality of vehicles into groups according to a preset condition, generates learning data in units of groups based on the learning battery information, and learns the learning data to construct the diagnostic model.

### CROSS-REFERENCE TO RELATED APPLICATION

This application claims the benefit of priority to Korean Patent Application No. 10-2023-0119785, filed in the Korean Intellectual Property Office on Sep. 8, 2023, the entire contents of which are incorporated herein by reference.

### TECHNICAL FIELD

The present disclosure relates to a vehicle control device, a system including the same, and a method thereof, and more specifically, to a technology for detecting an abnormality in a battery mounted on a vehicle.

### BACKGROUND

Vehicles designed to be environmentally friendly by utilizing electric energy as a power source, such as electric vehicles or hybrid vehicles, are equipped with batteries that store and release electric energy. Voltage variations can arise among these batteries due to structural differences, performance variations between cells, and variances in deterioration levels. These voltage variations can diminish efficiency of the battery. Consequently, minimizing the voltage difference between batteries is essential to enhance the overall efficiency of a vehicle battery.

Battery cell balancing technology can be employed to ameliorate voltage differences between batteries. In some examples, battery cell balancing adjusts the voltages of the batteries based on the battery with the lowest voltage, although this approach may result in some power loss.

Consequently, when the voltage difference between batteries is significant, more proactive measures such as battery replacement may become necessary. To address such issues, there has been a proposal for technology that detects abnormalities in batteries.

Achieving a more accurate detection of the abnormalities in batteries requires securing a substantial amount of abnormal data. However, obtaining meaningful abnormal data is challenging, given that such data is scarce compared to normal data.

Moreover, even when the batteries are identical, variations in battery characteristics may occur depending on the vehicle equipped with the battery.

In addition, the characteristics of the battery may exhibit variations based on the state of the vehicle.

### SUMMARY

The present disclosure is directed to a server for detecting an abnormality in a battery by securing data for detecting the abnormality in the battery, a method of constructing a diagnostic model therefor, and a method of detecting an abnormality in a battery using the same.

The present disclosure is also directed to a server configured to detect an abnormality in a battery by accurately detecting an abnormality in the battery by reflecting the characteristics of a vehicle on which the battery is mounted, a method of constructing a diagnostic model therefor, and a method of detecting the abnormality in the battery using the same.

The present disclosure is also directed to a server configured to detect an abnormality in a battery by accurately detecting an abnormality in the battery by reflecting the state of a vehicle on which the battery is mounted, a method of constructing a diagnostic model therefor, and a method of detecting the abnormality in the battery using the same.

According to an aspect of the present disclosure, a server for diagnosing a battery abnormality includes a memory that stores a diagnostic model for determining an abnormal state of a target battery, and a processor that is connected to the memory, wherein the processor classifies learning battery information in a form of time series data provided from each of a plurality of vehicles into groups according to a preset condition, generates learning data in units of groups based on the learning battery information, and learns the learning data to construct the diagnostic model.

According to an implementation, the processor may group the learning battery information in units of additional information that affects a change in the learning battery information.

According to an implementation, the processor may group additional information according to a vehicle model of each of the plurality of vehicle.

According to an implementation, the processor may preprocess the learning battery information to generate the learning data.

According to an implementation, the processor may obtain test data based on diagnostic battery information in the form of time series data on the target battery, learn the test data by using the diagnostic model, and determine an abnormal state of the target battery according to a learning result.

According to an implementation, the processor may output an error based on learning of the test data, and determine that the target battery is in an abnormal state when an accumulated error obtaining by accumulating the error is greater than a preset first threshold error.

According to an implementation, the processor may determine that the target battery is in an abnormal state when a number of times the error exceeds a preset second threshold value is greater than or equal to a preset threshold number.

According to an implementation, the processor may confirm a target vehicle equipped with the target battery, search for a target diagnostic model matching the target vehicle from among a plurality of diagnostic models, and learn the test data by using the target diagnostic model.

According to an implementation, the target diagnostic model may include two or more different diagnostic models.

According to an implementation, the target diagnostic model may include a first target diagnostic model matched with only the target vehicle, and a second target diagnostic model matched with the target vehicle and a vehicle other than the target vehicle.

According to another aspect of the present disclosure, a method of constructing a diagnostic model for diagnosing a battery abnormality includes classifying learning battery information in a form of time series data provided from each of a plurality of vehicles into groups according to a preset condition, generating learning data in units of groups based on the learning battery information, and constructing a diagnostic model by learning the learning data.

According to an implementation, the classifying of the learning battery information may include grouping the learning battery information in units of additional information that affects a change in the learning battery information.

According to an implementation, the classifying of the learning battery information may include grouping the additional information according to a vehicle model of each of the plurality of vehicle.

According to an implementation, the constructing of the diagnostic model may include constructing the diagnostic model by learning the learning data grouped in units of additional information.

According to an implementation, the constructing of the diagnostic model may include compressing the learning data by using the diagnostic model and restoring the compressed learning data to generate reconstruction data, and constructing the diagnostic model to derive a large reconstruction error between the learning data and the reconstruction data when the learning data is abnormal.

According to still another aspect of the present disclosure, a method of diagnosing a battery abnormality, which uses a diagnostic model constructed based on learning battery information in a form of time series data provided from each of a plurality of vehicles, includes generating test data based on diagnostic battery information in the form of time series data on a target battery that is to be diagnosed, learning the test data by using the diagnostic model, and determining an abnormal state of the target battery according to a learning result.

According to an implementation, the generating of the test data may include confirming a target vehicle equipped with the target battery, and searching for a target diagnostic model matching the target vehicle from among a plurality of diagnostic models.

According to an implementation, the searching of the target diagnostic model may include searching for a first target diagnostic model matched with only the target vehicle, and searching for a second target diagnostic model matched with the target vehicle and a vehicle other than the target vehicle.

According to an implementation, the determining of the abnormal state of the target battery may include determining that the battery is in an abnormal state when a first error obtained based on the first target diagnostic model and a second error obtained based on the second target diagnostic model are greater than or equal to a preset threshold error.

According to an implementation, the learning of the test data may include compressing the test data through an encoder of the diagnostic model, restoring the test data compressed through a decoder of the diagnostic model to obtain restored test data, and determining an abnormal state of the target battery based on a reconstruction error between the test data and the restored test data.

### BRIEF DESCRIPTION OF THE DRAWINGS

FIG. 1 is a diagram illustrating an example of a battery abnormal state diagnosis service.

FIG. 2 is a diagram illustrating an example of a battery abnormality diagnosis device.

FIG. 3 is a flowchart illustrating an example of a method of constructing a diagnostic model for detecting an abnormality in a battery.

FIG. 4 is a diagram illustrating an example of a method of classifying learning battery information into groups by a processor.

FIG. 5 is a diagram illustrating an example of an autoencoder.

FIG. 6 is a diagram illustrating an example of reconstruction error.

FIG. 7 is a flowchart illustrating an example of a method of detecting an abnormality in a battery.

FIG. 8 is a flowchart illustrating an example of a method of detecting an abnormality in a battery.

FIG. 9 is a flowchart illustrating an example of a method of detecting an abnormality in a battery.

FIG. 10 is a diagram illustrating an example of a method of collecting data on a target battery.

### DETAILED DESCRIPTION

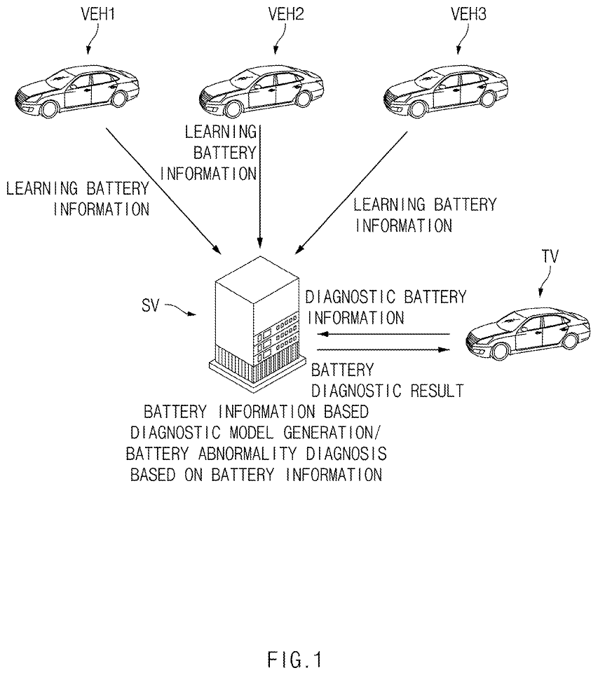

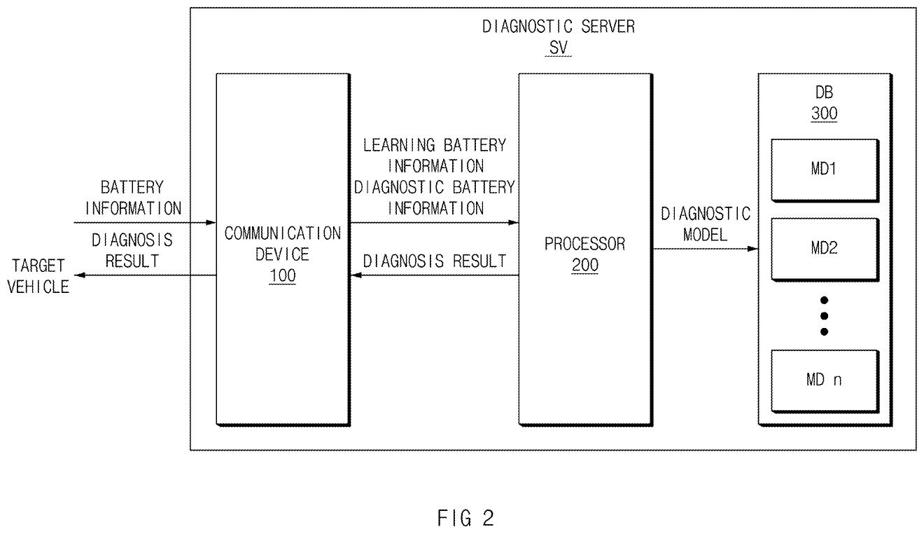

FIG. 1 is a diagram illustrating an example of a battery abnormal state diagnosis service. FIG. 2 is a diagram illustrating an example of a battery abnormality diagnosis device.

Referring to FIGS. 1 and 2, a battery abnormality diagnosis device can be implemented as a diagnostic server SV.

Vehicles VEH1, VEH2, and VEH3 and a target vehicle TV may be electric vehicles or hydrogen electric vehicles that are operated by using drive motors. The vehicles VEH1, VEH2, and VEH3 and the target vehicle TV can include batteries to operate their drive motors. The battery can be mounted in the form of a battery pack, and the battery pack can include a plurality of battery modules. In some implementations, each battery module can include a plurality of battery cells.

The target vehicle TV may serve as a vehicle that is configured to provide learning battery information for constructing a diagnostic model. In some implementations, the target vehicle TV may refer to a customer who has subscribed to a battery diagnosis service provided by the diagnostic server SV.

The diagnostic server SV can perform a battery diagnosis service. The battery diagnosis service may be a telemetric-based service. For example, the diagnostic server SV can obtain battery information of the vehicles VEH1, VEH2, and VEH3 from the plurality of vehicles VEH1, VEH2, and VEH3 in real time. In some implementations, the diagnostic server SV can construct diagnostic models MD1 to MD_n for battery diagnosis based on the received battery information and update the constructed diagnostic models MD1 to MD_n. In addition or alternatively, the diagnostic server SV may learn diagnostic battery information provided from the target vehicle TV and identify any abnormalities in the batteries mounted on the target vehicle TV.

The battery diagnosis service may refer to a service included in a telemetric service such as Blue Link. When using a telemetric service, the target vehicle TV can include solely battery information within the telemetric data before transmitting it to the diagnostic server SV.

In some implementations, data distinct from the current telemetric data of the battery diagnosis service can be transmitted to the diagnostic server SV. For example, logistics companies may refrain from using the current telemetric services due to their reluctance to disclose the location information of their vehicles. The diagnostic server SV can request only data for battery diagnosis from the vehicles VEH1, VEH2, and VEH3 by excluding location information from the battery information.

The configuration and operation of the diagnostic server SV are described as follows.

The diagnostic server SV can include a communication device 100, a processor 200, and a database 300.

The communication device 100 can receive battery information of the vehicles VEH1, VEH2, and VEH3. IN some implementations, the communication device can, for learning, receive, from the target vehicle TV, battery information for diagnosis.

The communication device 100 can transmit and receive radio signals with the vehicles VEH1, VEH2, and VEH3 or the target vehicle TV on a mobile communication network constructed according to technical standards or communication schemes for mobile communication. For example, the communication device 100 can perform communication based on global system for mobile communication (GSM), code division multi access (CDMA), code division multi access 2000 (CDMA2000), enhanced voice-data optimized or enhanced voice-data only (EV-DO), wideband CDMA (WCDMA), high speed downlink packet access (HSDPA), high speed uplink packet access (HSUPA), long term evolution (LTE), long term evolution-advanced (LTEA), and the like.

The processor 200 can generate learning data by classifying learning battery information provided from the vehicles VEH1, VEH2, and VEH3 into groups according to a preset condition. In some implementations, the processor 200 can learn learning data to construct a diagnostic model.

The learning battery information can include information regarding the voltage, current, temperature, charging capacity (State Of Charge: SOC), aging (State Of Health: SOH), total usage time, total charge/discharge amount, and the fast charging rate of the battery mounted on each vehicle.

The learning battery information can be presented in a time series format. For example, battery voltage may represent information measured over a period of time.

The learning battery information can be matched with vehicle model and additional information. The vehicle model can be a classification assigned by the manufacturer to identify the specific type of vehicle, such as IONIQ5®, IONIQ6®, IONIQ7®, and the like. The additional information may affect changes in learning battery information. For example, the additional information can include total driving distance, driving state, charging state, charger information, parking time, actual time, and the like. The driving state can be information such as whether the vehicles VEH1, VEH2, and VEH3 are in motion and their respective driving speeds at a time point when the learning battery information is obtained. The charging state can be information that distinguishes whether the learning battery information is obtained while charging, and can include information regarding whether the battery is charged through fast charging or slow charging.

In addition or alternatively, the processor 200 may preprocess the learning battery information to generate learning data.

The processor 200 can obtain test data based on diagnostic battery information provided from the target vehicle TV, and detect an abnormality in a target battery by learning the test data.

The diagnostic battery information can include information regarding the voltage, current, temperature, charging capacity (State Of Charge: SOC), aging (State Of Health: SOH), total usage time, total charge/discharge amount, and fast charging rate of the battery mounted on the target vehicle TV.

The diagnostic battery information can be time series data.

The diagnostic battery information can be matched with vehicle model and additional information. The additional information matching the diagnostic battery information can use the same classification criteria as the learning battery information.

In some implementations, the processor 200 can preprocess the diagnostic battery information to generate test data.

The database 300 can be a memory configured to store diagnostic models MD1 to MD_n.

Each of the diagnostic models MD1 to MD_n can be configured to simulate a human brain structure on a computer to detect an abnormality in a battery, and can include a plurality of network nodes having weights that simulate neurons of the human neural network. In some implementations, in a plurality of network nodes, a neuron that transmits and receives a signal through a synapse can transmit and receive data according to a connection relationship to simulate the synaptic activity of a neuron. The neural network can include a deep learning model developed from a neural network model. In a deep learning model, a plurality of network nodes can exchange data according to a convolutional connection relationship while being located in different layers. For example, a neural network model can include various deep learning schemes such as a deep neural network (DNN), a convolutional deep neural network (CNN), a recurrent Boltzmann machine (RNN), a restricted Boltzmann machine (RBM), a deep belief network (DBN), a deep Q-network, and the like.

The database 300 may be a memory that serves as a storage facility for artificial intelligence (AI) processors and algorithms. The memory can include a hard disk drive, a flash memory, an electrically erasable programmable read-only memory (EEPROM), a static RAM (SRAM), a ferro-electric RAM (FRAM), a phase-change RAM (PRAM), a magnetic RAM (MRAM), a dynamic random access memory (DRAM), a synchronous dynamic random access memory (SDRAM), a double date rate-SDRAM (DDR-SDRAM), and the like.

In some implementations, the diagnostic models MD1 to MD_n can be included in the processor 200. For example, operations performed by the processor 200 can include operations performed by the diagnostic models MD1 to MD_n.

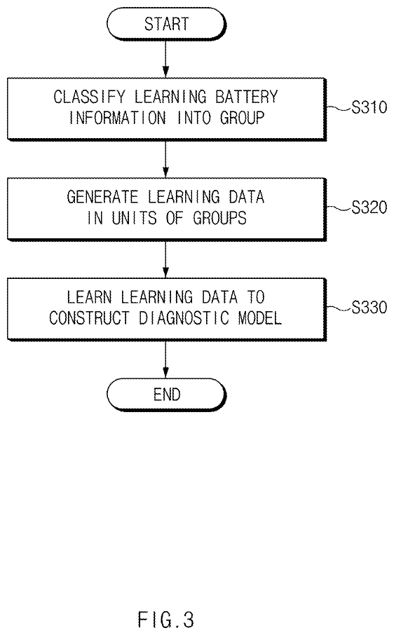

FIG. 3 is a flowchart illustrating an example of a method of constructing a diagnostic model for detecting an abnormality in a battery. The procedures shown in FIG. 3 can be performed by a processor of a server.

In S310, the processor 200 can classify learning battery information into groups.

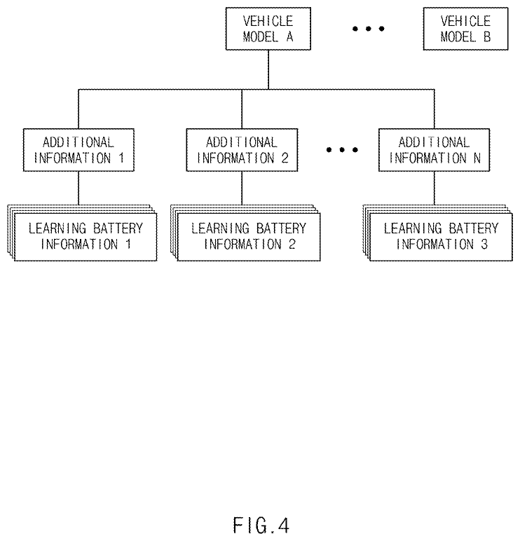

FIG. 4 is a diagram illustrating an example of a method of classifying learning battery information into groups by a processor.

Referring to FIG. 4, the processor 200 can classify learning battery information based on the vehicle model and additional information.

The processor 200 can identify the vehicle model of the learning battery information provided through the communication device 100. In addition, the processor 200 can identify additional information of the learning battery information. The processor 200 can group the learning battery information having the same vehicle model and the same additional information into a single group. For example, the processor 200 can group learning battery information 1, associated with vehicle model A and corresponding to additional information 1, into a single group from the learning battery information provided from the vehicles VEH1, VEH2, and VEH3.

In S320, the processor 200 can generate learning data in units of groups.

As shown in FIG. 4, the processor 200 can classify learning battery information belonging to the same group into the same learning data group. For example, the processor 200 can group learning battery information 1 into a single learning data group.

The processor 200 can preprocess the learning battery information to generate the learning data.

For example, the preprocessing operation can include removing learning battery information that exhibits significant defects or deviates substantially from the general trend of battery information.

In addition, the preprocessing operation can include processing data to easily apply the learning data to a diagnostic model. As a result, the specifics of the preprocessing operation may vary depending on the type of diagnostic model.

The preprocessing operation can include vectorization and normalization. The vectorization can include converting the learning battery information into a tensor. The normalization can include adjusting the learning battery information to a size within a certain range. Data with significant or uneven values may not be appropriate as input to a diagnostic model. Thus, the processor 200 may normalize the learning battery information ensuring it falls within a specified range, such as 0 (zero) to 1.

In S330, the processor 200 can learn the learning data to construct a diagnostic model.

The diagnostic model can be implemented based on an autoencoder.

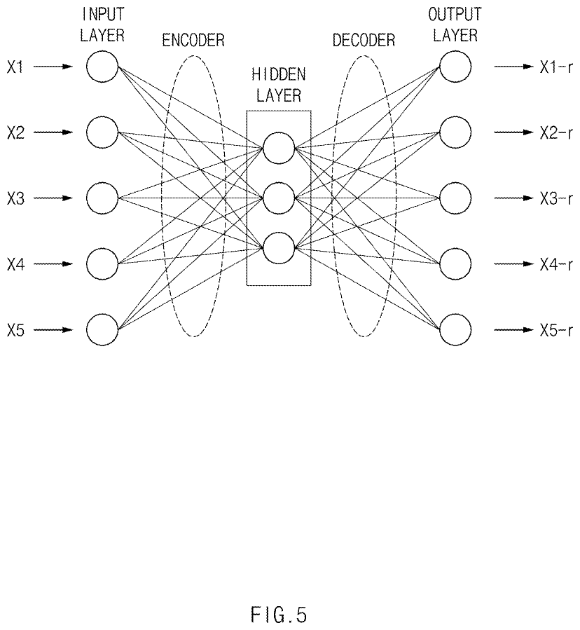

FIG. 5 is a diagram illustrating an example of an autoencoder.

Referring to FIG. 5, an autoencoder-based diagnostic model can include an encoder and a decoder.

The encoder can compress the learning data input to an input layer and output it to a hidden layer. The decoder can output data of the hidden layer through an output layer. In FIGS. 5, X1, X2, X3, X4, and X5 may represent learning data input to the encoder, and X1-1, X2-1, X3-1, X4-1 and X5-1 may represent reconstruction data output through the decoder.

The processor 200 can obtain an reconstruction error between the learning data and the reconstruction data, and can construct a diagnostic model by reflecting a size of the reconstruction error.

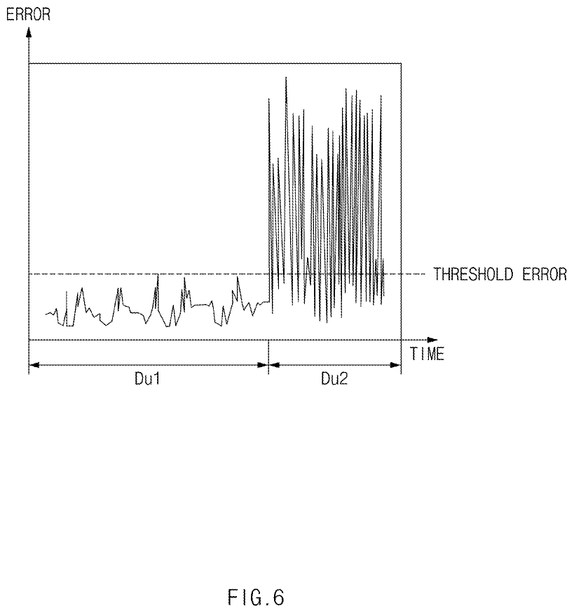

FIG. 6 is a diagram illustrating an example of reconstruction error.

Referring to FIG. 6, the processor 200 can obtain a reconstruction error according to a result of learning the learning data by using a diagnostic model. The reconstruction error can refer to the difference between the learning data and the reconstruction data.

A first period Du1 may be a period in which normal data is learned as the learning data, and a second period Du2 may be a period in which abnormal data is learned as the learning data. When the learning data is normal, a relatively small reconstruction error may be obtained. Conversely, when the learning data is abnormal, the reconstruction error may be obtained at a higher value. For example, when the learning data is normal, the reconstruction error may be less than a threshold error, and when the learning data is abnormal, the reconstruction error may exceed the threshold error.

The objective of constructing a diagnostic model may be to establish a connection between the normality of the learning data and the threshold error. For example, the diagnostic model can be constructed to ensure that the reconstruction error exceeds a preset threshold error when abnormalities are present in the learning data.

In addition, the threshold error can be used to distinguish normal/abnormal test data obtained based on battery information.

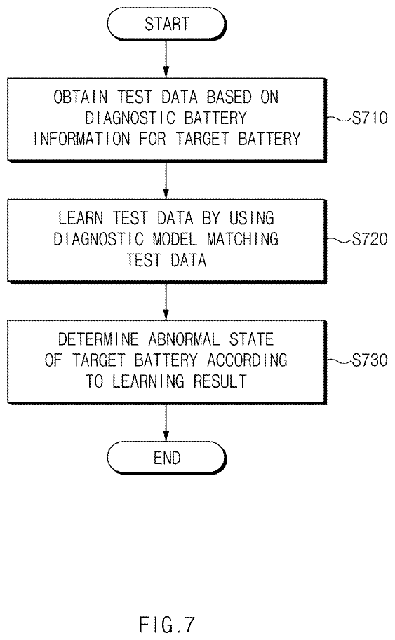

FIG. 7 is a flowchart illustrating an example of a method of detecting an abnormality in a battery. The procedures shown in FIG. 7 can be performed by the processor shown in FIG. 2.

In S710, the processor 200 can obtain test data based on diagnostic battery information for a target battery.

The diagnostic battery information can be data including the characteristics of the target battery mounted on the target vehicle TV, and can be time series data to be matched with the vehicle model and additional information of the target vehicle TV. The additional information can be classified based on the same reference as learning battery information.

The processor 200 can classify diagnostic battery information according to the target vehicle.

In some implementations, the processor 200 can search for a target diagnostic model that matches the target vehicle and preprocess diagnostic battery information corresponding to the target diagnostic model. The preprocessing operation for diagnostic battery information may use the same procedure as the preprocessing operation for learning battery information.

In S720, the processor 200 can learn the test data by using the diagnostic model that matches the test data.

In S730, the processor 200 can detect an abnormality in the target battery according to the learning result.

In some implementations, the processor 200 can output an error based on learning of the test data, and when the error exceeds a preset first threshold value, the processor 200 can detect an abnormality in the target battery.

In some implementations, the processor 200 can accumulate errors output as a learning result, and when the accumulated error exceeds the first threshold value, the processor 200 can detect an abnormality in the target battery.

In some implementations, the processor 200 can count the number of times the error output as the learning result exceeds the first threshold value, and when the counted number is equal to or greater than a second threshold value, the processor 200 can detect an abnormality in the target battery.

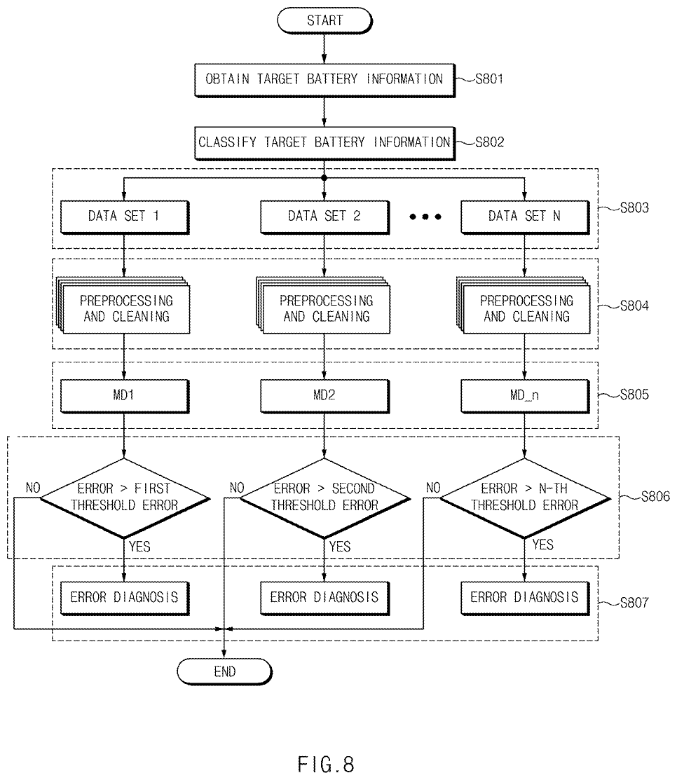

FIG. 8 is a flowchart illustrating an example of a method of detecting an abnormality in a battery.

Referring to FIG. 8, in operation S801, the processor 200 can obtain target battery information. The target battery information can be provided from the target vehicle TV.

In operations S802 and S803, the processor 200 can classify target battery information and generate a data set.

The processor 200 can generate a data set by classifying the target battery information in the same manner as the criterion for classifying the learning battery information shown in FIG. 4.

In addition or alternatively, the processor 200 can generate the data set by classifying the target battery information based on the vehicle model of the target vehicle. For example, the target battery information corresponding to vehicle model A may be classified as data set 1.

In operation S804, the processor 200 can preprocess and clean data sets to generate the test data.

In operation S805, the processor 200 can select a diagnostic model that matches the test data and proceed with learning. For example, when vehicle model A matches a first diagnostic model MD1, the processor 200 can input the test data generated based on data set 1 to the first diagnostic model MD1.

In operation S806 and operation S807, the processor 200 can detect an abnormality in the target battery based on the output of the diagnostic model. For example, when the first error output by the first diagnostic model MD1 exceeds the first threshold error, the processor 200 can detect an abnormality in the target battery.

The first threshold error to the n-th threshold error (n is a natural number) for determining whether each of the diagnostic models MD1 to MD_n is out of order can be set to different sizes.

In addition, the first threshold error to the n-th threshold error can have different characteristics depending on the diagnostic model. For example, the first threshold error to the n-th threshold error can be used to compare reconstruction errors or other error characteristics.

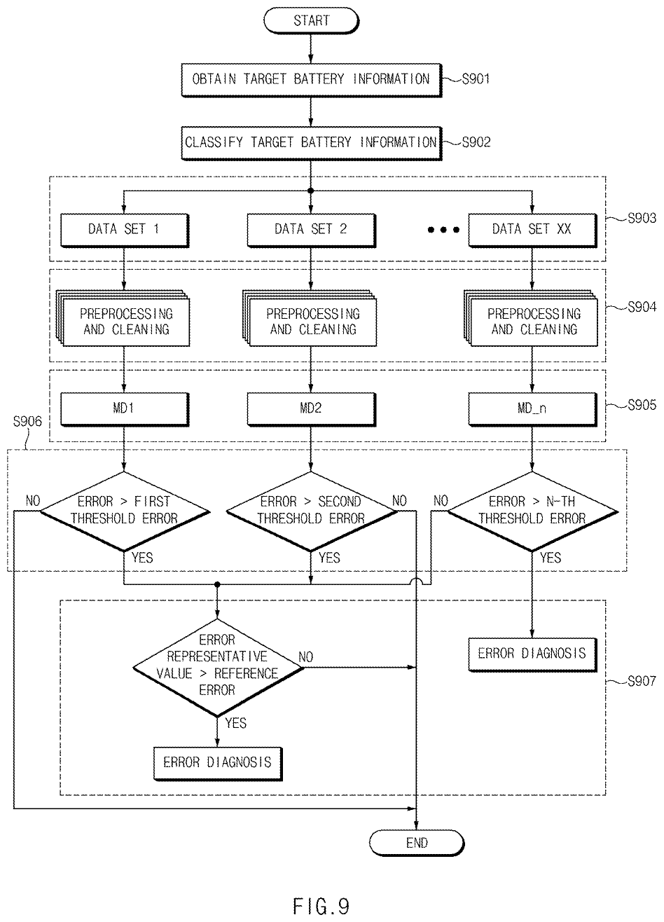

FIG. 9 is a flowchart illustrating an example of a method of detecting an abnormality in a battery.

Referring to FIG. 9, in operation S901, the processor 200 can obtain the target battery information.

In operations S902 and operation S903, the processor 200 can classify the target battery information and generate a data set.

In addition or alternatively, the processor 200 can generate the data set by classifying the target battery information based on the vehicle model of the target vehicle. When the plurality of diagnostic models match the vehicle model, the processor 200 can generate a data set corresponding to each diagnostic model. For example, when the first diagnostic model MD1 and the second diagnostic model MD2 learn the battery information of vehicle model A, the processor 200 can generate data set 1 and data set 2 based on the battery information of vehicle model A.

In operation S904, the processor 200 can preprocess and clean data sets to generate the test data.

In operation S905, the processor 200 can select a diagnostic model that matches the test data and proceed with learning.

In operations S906 and operation S907, the processor 200 can detect an abnormality in the target battery based on the output of the diagnostic model.

The processor 200 can detect an abnormality in the target battery by using two or more diagnostic models. When data set 1 and data set 2 include the same target battery information, the processor 200 can detect an abnormality in the target battery by using the first diagnostic model MD1 and the second diagnostic model MD2.

For example, when the first error output by the first diagnostic model MD1 exceeds the first threshold error and the second error output by the second diagnostic model MD2 exceeds the second threshold error, the processor 200 can obtain a representative error value based on the first error and the second error. The error representative value can be the sum or average of the first error and the second error. The processor 200 can compare the error representative value with the reference error, and can detect an abnormality in the target battery when the error representative value is greater than or equal to the reference error.

In addition or alternatively, when the first error output by the first diagnostic model MD1 exceeds the first threshold error and the second error output by the second diagnostic model MD2 exceeds the second threshold error, the processor 200 can detect an abnormality in the target battery.

In some implementations, the first diagnostic model MD1 and the second diagnostic model MD2 can be used for learning a battery mounted on the same target vehicle and may be different from each other.

In addition or alternatively, the first diagnostic model MD1 can be a diagnostic model targeting only the target vehicle, and the second diagnostic model MD2 can be a diagnostic model targeting vehicles other than the target vehicle.

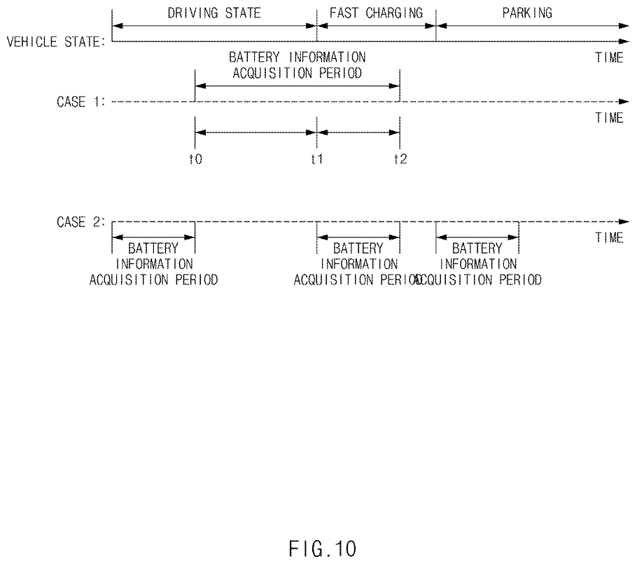

FIG. 10 is a diagram illustrating an example of a method of collecting data on a target battery.

Referring to FIG. 10, a battery information acquisition period of the target battery can be set based on time and vehicle condition. The battery information acquisition period can be a period during which the target vehicle TV obtains target battery information. The vehicle condition can correspond to factors that affect the battery and can be a reference for classifying additional information.

Case 1 illustrates an example of obtaining battery information of a target battery based on a reference time. The battery information acquisition period can be determined as a preset time. For example, the battery information acquisition period can be from t0 to t2, and can be a constant time regardless of the vehicle condition. As shown in FIG. 10, the period from t0 to t2 can be a period including a driving state and a fast charging state. Therefore, the target battery information in Case 1 can include information about the driving state from to to t1 and battery information about the fast charging period from t1 to t2.

In Case 1, because target battery information is obtained during a set time without considering the vehicle condition, it may be difficult to obtain target battery information for various additional information.

Case 2 illustrates an example of obtaining target battery information by considering vehicle condition. In Case 2, a certain period of time can be set as the battery information acquisition period whenever the vehicle condition changes. Therefore, because various additional information is obtained in Case 2, an abnormality in the target battery can be detected in various vehicle conditions.

In some implementations, it is possible to more easily secure data for detecting an abnormality in a battery by obtaining learning battery information from a plurality of vehicles.

In addition, because a diagnostic model is generated according to the vehicle model of a vehicle on which a battery is mounted, and the abnormality diagnosis of the battery mounted on a target vehicle is performed using the diagnostic model, it is possible to more accurately detect an abnormality in the battery by reflecting the vehicle characteristics.

In addition, a diagnostic model can be constructed based on additional information reflecting the state of a vehicle that affects a battery, so that it is possible to more accurately detect an abnormality in the battery.

In addition, various effects that are directly or indirectly understood through the present disclosure may be provided.

Although exemplary implementations of the present disclosure have been described for illustrative purposes, those skilled in the art will appreciate that various modifications, additions and substitutions are possible, without departing from the scope and spirit of the disclosure.

Therefore, the exemplary implementations disclosed in the present disclosure are provided for the sake of descriptions, not limiting the technical concepts of the present disclosure, and it should be understood that such exemplary implementations are not intended to limit the scope of the technical concepts of the present disclosure. The protection scope of the present disclosure should be understood by the claims below, and all the technical concepts within the equivalent scopes should be interpreted to be within the scope of the right of the present disclosure.

What is claimed is:

1. A server configured to detect an abnormality in a battery, the server comprising:
a memory configured to store instructions and a diagnostic model for detecting an abnormality in a target battery; and
a processor connected to the memory and configured to execute the instructions to perform operations comprising:
classifying learning battery information in a time series format, provided from each of plurality of vehicles, into groups based on a preset condition;
generating learning data in units of groups based on the classified learning battery information; and
learning the generated learning data to construct the diagnostic model.

2. The server of claim 1, wherein classifying the learning battery information comprises grouping the learning battery information based on additional information associated with a change in the learning battery information.

3. The server of claim 1, wherein classifying the learning battery information comprises grouping additional information based on a vehicle model of each of the plurality of vehicles.

4. The server of claim 1, wherein generating the learning data comprises preprocessing the learning battery information to generate the learning data.

5. The server of claim 4, wherein the operations further comprise:
obtaining test data based on diagnostic battery information regarding the target battery, the diagnostic battery information being in the time series format;
learning the test data by using the diagnostic model; and
detecting the abnormality in the target battery based on a learning result from the diagnostic model.

6. The server of claim 5, wherein detecting the abnormality comprises:
outputting an error based on the learning result from the diagnostic model, and
detecting the abnormality in the target battery based on a determination that an accumulated error obtained by accumulating the error is greater than a first preset threshold.

7. The server of claim 6, wherein detecting the abnormality in comprises detecting the abnormality in the target battery based on a determination that a number of times the error exceeds a preset second threshold is greater than or equal to a preset threshold number.

8. The server of claim 5, wherein the operations further comprise:
confirming a target vehicle equipped with the target battery,
searching for a target diagnostic model associated with the target vehicle from among a plurality of diagnostic models, and
learning the test data by using the target diagnostic model.

9. The server of claim 8, wherein the target diagnostic model includes a plurality of distinct diagnostic models.

10. The server of claim 8, wherein the target diagnostic model includes:
a first target diagnostic model associated only with the target vehicle; and
a second target diagnostic model associated with the target vehicle and a vehicle other than the target vehicle.

11. A method of constructing a diagnostic model for diagnosing a battery abnormality, the method comprising:
classifying learning battery information in a form of time series data provided from each of a plurality of vehicles into groups according to a preset condition;
generating learning data in units of groups based on the learning battery information; and
constructing a diagnostic model by learning the learning data.

12. The method of claim 11, wherein the classifying of the learning battery information includes:
grouping the learning battery information in units of additional information that affects a change in the learning battery information.

13. The method of claim 12, wherein the classifying of the learning battery information includes:
grouping additional information according to a vehicle model of each of the plurality of vehicles.

14. The method of claim 13, wherein the constructing of the diagnostic model includes:
constructing the diagnostic model by learning the learning data grouped in units of additional information.

15. The method of claim 11, wherein the constructing of the diagnostic model includes:
compressing the learning data by using the diagnostic model and restoring the compressed learning data to generate reconstruction data; and
constructing the diagnostic model to derive a large reconstruction error between the learning data and the reconstruction data based on a determination that the learning data is abnormal.

16. A method of diagnosing a battery abnormality, which uses a diagnostic model constructed based on learning battery information in a form of time series data provided from each of a plurality of vehicles, the method comprising:
generating test data based on diagnostic battery information in the form of time series data on a target battery that is to be diagnosed;
learning the test data by using the diagnostic model; and
determining an abnormal state of the target battery according to a learning result.

17. The method of claim 16, wherein the generating of the test data includes:
confirming a target vehicle equipped with the target battery; and
searching for a target diagnostic model matching the target vehicle from among a plurality of diagnostic models.

18. The method of claim 17, wherein the searching of the target diagnostic model includes:
searching for a first target diagnostic model matched with only the target vehicle; and
searching for a second target diagnostic model matched with the target vehicle and a vehicle other than the target vehicle.

19. The method of claim 18, wherein the determining of the abnormal state of the target battery includes:
determining that the target battery is in an abnormal state based on a determination that a first error obtained based on the first target diagnostic model and a second error obtained based on the second target diagnostic model are greater than or equal to a preset threshold error.

20. The method of claim 16, wherein the learning of the test data includes:
compressing the test data through an encoder of the diagnostic model;
restoring the test data compressed through a decoder of the diagnostic model to obtain restored test data; and
determining an abnormal state of the target battery based on a reconstruction error between the test data and the restored test data.
